(19) United States
(12) Patent Application Publication
(10) Pub. No.: US 2016/0181514 A1
(43) Pub. Date: Jun. 23, 2016

(54) ELECTRONIC DEVICE AND METHOD FOR FABRICATING THE SAME

(71) Applicant: SK hynix Inc., Icheon-Si (KR)

(72) Inventors: Guk-Cheon Kim, Icheon-si (KR); Ki-Seon Park, Icheon-Si (KR); Bo-Mi Lee, Icheon-Si (KR); Won-Joon Choi, Icheon-Si (KR); Yang-Kon Kim, Icheon-Si (KR)

(21) Appl. No.: 14/788,420

(22) Filed: Jun. 30, 2015

(30) Foreign Application Priority Data
Dec. 17, 2014 (KR) 10-2014-0182699

(51) Int. Cl. H01L 43/10; H01L 43/02; G06F 3/06; H01L 43/08

(52) U.S. Cl. CPC H01L 43/10; H01L 43/08; H01L 43/02; G06F 3/0604; G06F 3/0659; G06F 3/0679

(57) ABSTRACT

Disclosed are an electronic device comprising a semiconductor memory and a method for fabricating the same, which enable the characteristics of a variable resistance element to be improved. The electronic device includes a semiconductor memory. The semiconductor memory includes a variable resistance element including a stack of a pinned layer, a tunnel barrier layer and a variable layer. The variable layer may include a material layer having a standard electrode potential higher than that of Fe. According to the electronic device including the semiconductor memory and the method for fabricating the same according to the implementation of the disclosed technology, the characteristics of the variable resistance element may be improved.

### CROSS-REFERENCE TO RELATED APPLICATIONS

The present application claims priority of Korean Patent Application No. 10-2014-0182699, entitled “ELECTRONIC DEVICE AND METHOD FOR FABRICATING THE SAME” and filed on Dec. 17, 2014, which is incorporated herein by reference in its entirety.

### TECHNICAL FIELD

This patent document relates to memory circuits or devices and their applications in electronic devices or systems.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device in which the characteristics of a variable resistance element may be improved.

In one aspect, an electronic device including a semiconductor memory is provided to comprise a variable resistance element comprising a stack of a pinned layer, a tunnel barrier layer and a variable layer, wherein the variable layer includes a material layer having a standard electrode potential higher than that of Fe.

Implementations of the above electronic device may include one or more the following.

In some implementations, the pinned layer includes a material layer including Fe. In some implementations, the variable layer includes an alloy of a material including Fe and a material having a standard electrode potential higher than that of Fe, and a content of Fe in the variable layer spatially increases towards the tunnel barrier layer. In some implementations, the variable layer includes a stack of a material layer including Fe and a material layer having a standard electrode potential higher than that of Fe, and the material layer including Fe is positioned in a portion that comes in contact with the tunnel barrier layer. In some implementations, the variable layer includes an SAF (Synthetic Antiferromagnetic) structure comprising a stack of a magnetic layer including a material having a standard electrode potential higher than that of Fe, a spacer layer and a ferromagnetic layer. In some implementations, the spacer layer includes Ru, Cr, Cu, Ti or W. In some implementations, the material layer having a standard electrode potential higher than that of Fe includes Cd, Ni, Sn, Sb, Ag or Pd. In some implementations, the variable layer includes any alloy including Fe—Pt alloy, Fe—Pd alloy, Co—Fe alloy, Fe—Ni—Pt alloy or Co—Fe—Pt alloy, or a stack structure including Fe/Pd or Fe/Pt. The variable layer further includes boron (B) as an impurity in the alloy or the stack structure. In some implementations, the pinned layer includes a single layer including an Fe—Pt alloy, an Fe—Pd alloy, a Co—Pd alloy, a Co—Pt alloy, a Co—Fe alloy, an Fe—Ni—Pt alloy, a Co—Fe—Pt alloy or a Co—Ni—Pt alloy, or a multilayer structure including two or more of the Fe—Pt alloy, the Fe—Pd alloy, the Co—Pd alloy, the Co—Pt alloy, the Co—Fe alloy, the Fe—Ni—Pt alloy, the Co—Fe—Pt alloy or the Co—Ni—Pt alloy, or a stack structure including Co/Pt, Co/Pd, Fe/Pd or Fe/Pt. In some implementations, the pinned layer further includes boron (B) as an impurity in the single layer, the multilayer structure or the stack structure. In some implementations, the variable resistance element further includes a seed layer located in bottom portion of the variable resistance element, and a capping layer located in top portion of the variable resistance element. In some implementations, the seed layer or the capping layer includes any one or a combination of two or more selected from Ta, Ru, PtMn, Al, Hf, Cr, W, Ti, TaN, AlN, HfN, CrN, WN or TiN. In some implementations, the tunnel barrier layer includes a single layer including Al₂O₃, MgO, CaO, SrO, TiO, VO or NbO, or a multilayer structure including two or more of Al₂O₃, MgO, CaO, SrO, TiO, VO or NbO.

In some implementations, the electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory unit that includes the resistance variable element is part of the memory unit in the microprocessor.

In some implementations, the electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory unit that includes the resistance variable element is part of the cache memory unit in the processor.

In some implementations, the electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the semiconductor memory unit that includes the resistance variable element is part of the auxiliary memory device or the main memory device in the processing system.

In some implementations, the electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory unit that includes the resistance variable element is part of the storage device or the temporary storage device in the data storage system.

In some implementations, the electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory unit that includes the resistance variable element is part of the memory or the buffer memory in the memory system.

In an implementation, a method for fabricating an electronic device include a semiconductor memory, the method comprising: forming over a substrate a variable resistance element comprising a stack of a pinned layer, a tunnel barrier layer and a variable layer; forming a top electrode contact in contact with the variable resistance element; and forming a conductive line connected to the variable resistance element through the top electrode contact; wherein the variable layer includes a material layer that includes Fe and a content of Fe spatially varies within the variable layer.

Implementations of the above method may include one or more of the following.

In some implementations, the variable layer includes a material layer that has a standard electrode potential higher than a standard electrode potential of Fe. In some implementations, the pinned layer includes a material layer including Fe. In some implementations, the variable layer includes an alloy of a material including Fe and a material having a standard electrode potential higher than that of Fe, and a content of Fe in the variable layer spatially increases towards the tunnel barrier layer. In some implementations, the variable layer comprises a stack of a material layer including Fe and a material layer having a standard electrode potential higher than that of Fe, and the material layer including Fe is positioned in a portion that comes in contact with the tunnel barrier layer. In some implementations, the variable layer includes an SAF structure comprising a stack of a magnetic layer including a material having the standard electrode potential higher than Fe, a spacer layer and a ferromagnetic layer. In some implementations, the spacer layer includes Ru, Cr, Cu, Ti or W. In some implementations, the material layer having a standard electrode potential higher than that of Fe includes Cd, Ni, Sn, Sb, Ag or Pd. In some implementations, the tunnel barrier layer comprises a single layer including Al₂O₃, MgO, CaO, SrO, TiO, VO or NbO, or a multilayer structure including two or more ofAl₂O₃, MgO, CaO, SrO, TiO, VO or NbO. In some implementations, the method may further includes: before forming the variable resistance element, forming a first interlayer insulating layer over the substrate, and forming a bottom electrode contact through the first interlayer insulating layer so as to come in contact with the substrate. In some implementations, the forming of the top electrode contact comprises: forming a second interlayer insulating layer over the substrate to cover the variable resistance element; forming a contact hole through the second interlayer insulating layer so as to expose a portion of the variable resistance element; and filling a conductive material in the contact hole.

### BRIEF DESCRIPTION OF THE DRAWINGS

FIG. 1 is a cross-sectional view illustrating a variable resistance element according to one implementation of the disclosed technology.

FIGS. 2A to 2C are cross-sectional views illustrating a magnetic layer according to one implementation of the disclosed technology.

FIG. 3 is a cross-sectional view illustrating a semiconductor device according to one implementation of the disclosed technology.

FIGS. 4A to 4I are cross-sectional views illustrating a method for fabricating a semiconductor device according to one implementation of the disclosed technology.

FIG. 5 is an example of configuration diagram of a microprocessor implementing memory circuitry based on the disclosed technology.

FIG. 6 is an example of configuration diagram of a processor implementing memory circuitry based on the disclosed technology.

FIG. 7 is an example of configuration diagram of a system implementing memory circuitry based on the disclosed technology.

FIG. 8 is an example of configuration diagram of a data storage system implementing memory circuitry based on the disclosed technology.

FIG. 9 is an example of configuration diagram of a memory system implementing memory circuitry based on the disclosed technology.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

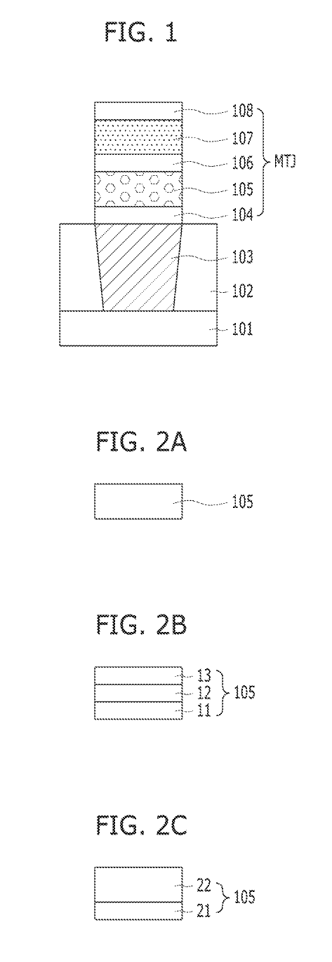

FIG. 1 is a cross-sectional view illustrating a variable resistance element according to one implementation of the disclosed technology.

As shown in FIG. 1, a semiconductor device in accordance with one implementation of the disclosed technology may include: a substrate 101 having a certain required structure that is formed on the substrate 101, for example, a switching element; a first interlayer insulating layer 102 formed on the substrate 101; and a bottom electrode contact 103 formed through the first interlayer insulating layer 102 to electrically connect one end of the switching element to a variable resistance element MTJ. The variable resistance element including a MTJ (Magnetic Tunnel Junction) structure may be formed on the first interlayer insulating layer 102.

The switching element is configured to select a specific unit cell from a semiconductor device including a plurality of unit cells. The switching element may be disposed in each unit cell and may include a transistor, or a diode, etc. One end of the switching element may be electrically connected to a first contact plug 103 and the other end of the switching element may be electrically connected to a source line (not shown).

The first interlayer insulating layer 102 may be formed of or include a single layer including an oxide layer, a nitride layer or an oxynitride layer, or a stack of two or more of these layers.

The variable resistance element may include a magnetic tunnel junction (MTJ) structure including a variable layer 105 having a variable magnetization direction, a pinned layer 107 having a fixed magnetization direction, and a tunnel barrier layer 106 interposed between the variable layer 105 and the pinned layer 107.

Herein, the variable layer 105 has a variable magnetization direction, and thus can actually store data according to the magnetization direction of the variable layer 105 with respect to the fixed magnetization direction of the pinned layer 107. The variable layer 105 may be referred to as a free layer, or a storage layer, etc.

In particular, the variable layer 105 in this implementation may include a material, which can lower the saturation magnetization of a ferromagnetic material and does not break an orbital bond between iron (Fe) and oxygen (O) atoms that exhibit perpendicular magnetic properties at the interfaces between the tunnel barrier layer 106 and the magnetic layers 105 and 107. Therefore, the material that is added to the variable layer 105 may include an element having a standard electrode potential higher than the standard electrode potential of Fe (−0.44 V), which is less susceptible to oxidation than Fe.

Table 1 below shows the standard electrode potentials of various elements.

TABLE 1

| Atomic Number | Element | Standard Electrode Potential (V) |
|---|---|---|
| 26 | Fe | −0.44 |
| 48 | Cd | −0.4025 |
| 27 | Co | −0.277 |
| 28 | Ni | −0.257 |
| 50 | Sn | −0.138 |
| 82 | Pb | −0.126 |
| 2 | H | 0 |
| 51 | Sb | 0.1504 |
| 83 | Bi | 0.3172 |
| 80 | Hg | 0.796 |
| 47 | Ag | 0.799 |
| 46 | Pd | 0.915 |
| 78 | Pt | 1.188 |
| 79 | Au | 1.52 |

As shown in Table 1 above, a material having a standard electrode potential higher than Fe, which may be added to the magnetic layer 105, may include Cd, Ni, Sn, Sb, Ag or Pd.

If a material having a standard electrode potential higher than that of iron (Fe) is added to the variable layer 105 to lower the saturation magnetization (Ms) of the variable layer 105, it is possible to increase the thickness of the variable layer 105 while maintaining the perpendicular magnetic properties. Therefore, the damping constant and spin polarization of the variable resistance element may be enhanced.

For example, the variable layer 105 may be composed of or include an alloy of a material including Fe and a material having a standard electrode potential higher than that of Fe, and in this case, the content of Fe in the variable layer 105 may vary spatially with a position within the variable layer 105 and may, e.g., spatially increase towards the tunnel barrier layer 106 (i.e., spatially increase with position in the variable layer 105 as the position gets closer to the interface with the tunnel barrier layer 106). In addition, the variable layer 105 may be composed of or include a stack of a material layer including Fe and a material layer having a standard electrode potential higher than that of Fe, and in this case, the material layer including Fe may be positioned at a portion that comes in contact with the tunnel barrier layer 106.

Furthermore, the variable layer 105 may include a synthetic antiferromagnetic (SAF) structure including a stack of a magnetic layer including a material having a standard electrode potential higher than that of Fe, a spacer layer, and a ferromagnetic layer. The spacer layer may, for example, include Ru, Cr, Cu, Ti or W.

In addition, the variable layer 105 may include Fe—Pt alloy, an Fe—Pd alloy, a Co—Fe alloy, an Fe—Ni—Pt alloy or a Co—Fe—Pt alloy, or a stack structure including Fe/Pd or Fe/Pt. In addition, the variable layer 105 may further include an impurity such as boron (B) in the above-described alloy or stack structure.

The pinned layer 107 has a fixed magnetization direction that can be contrasted with that of the variable layer 105, and it may be referred to as a pinned layer, a reference layer, etc.

The pinned layer 107 may be or include, for example a material layer including Fe. For example, the pinned layer 107 may include a single layer including an Fe—Pt alloy, an Fe—Pd alloy, a Co—Pd alloy, a Co—Pt alloy, a Co—Fe alloy, an Fe—Ni—Pt alloy, a Co—Fe—Pt alloy or a Co—Ni—Pt alloy, or a multilayer structure including two or more of these alloys, or a stack structure including Co/Pt, Co/Pd, Fe/Pd or Fe/Pt. Also, the pinned layer 107 may further include an impurity such as boron B in the above-described single layer, multilayer structure or stack structure.

In this variable resistance element MTJ, the magnetization direction of the variable layer 105 may change depending on the voltage or current applied thereto, so as to be parallel or anti-parallel with that of the pinned layer 107. As the result, the variable resistance element may be switched between a low-resistance state and a high-resistance state.

The tunnel barrier layer 106 allows the tunneling of electrons, which enables a change in the magnetization direction of the variable layer. The tunnel barrier layer 106 may be or include a single layer or multilayer structure including a dielectric material, for example, an oxide such as Al₂O₃, MgO, CaO, SrO, TiO, VO or NbO, but is not limited thereto.

In addition, the variable resistance element may further include a seed layer 104 and a capping layer 108 under the variable layer 105 and over the pinned layer 107, respectively, in order to enhance the characteristics of the variable resistance element or facilitate the fabrication process. In this implementation, the variable layer 105 is positioned in the bottom portion of the variable resistance element, and the pinned layer 107 is positioned in the top portion of the variable resistance element. However, the positions of the variable layer 105 and the pinned layer 107 are not limited thereto, and may be changed as needed. In addition, because the seed layer 104 and the capping layer 108 are positioned in the bottom portion and the top portion of the variable resistance element, respectively, the positions of these layers may be maintained if the positions of the variable layer 105 and the pinned layer 107 are changed with respect to each other.

FIGS. 2A to 2C are cross-sectional views illustrating a variable layer in accordance with one implementation of the disclosed technology.

As shown in FIG. 2A, the variable layer 105 may include a magnetic layer containing or including a material capable of lowering the saturation magnetization of a ferromagnetic material, for example, a material having a standard electrode potential higher than that of Fe. When the variable layer 105 is composed of or includes an alloy of a material including Fe and a material having a standard electrode potential higher than that of Fe, the content of Fe in the variable layer 105 may spatially vary with the position within the variable layer 105 and may, e.g., increase with the position within the variable layer 105 as the positon approaches to or gets closer to the interface with the tunnel barrier layer 106.

As shown in FIG. 2B, the variable layer 105 may include a stack of a magnetic layer 11 including a material having a standard electrode potential higher than that of Fe, a spacer layer 12 and a ferromagnetic layer 13. The stacking order of these layers is changeable as needed. The spacer layer 12 may, for example, include Ru, Cr, Cu, Ti or W. The ferromagnetic layer 13 may include alloys described with reference to FIG. 1. Further, the ferromagnetic layer 13 may include, for example, any one stack structure including Co/Pt, Co/Pd, Fe/Pd or Fe/Pt, in addition to the alloys described with reference to FIG. 1.

As shown in FIG. 2C, the variable layer 105 may include a stack of a material layer 22 including Fe and a material layer 21 having a standard electrode potential higher than that of Fe. The material layer 22 including Fe may be positioned to come in contact with the tunnel barrier layer. The magnetic layer structures shown in FIGS. 2A to 2C are provided as examples, and the magnetic layer of the disclosed technology may include other applicable stack structures.

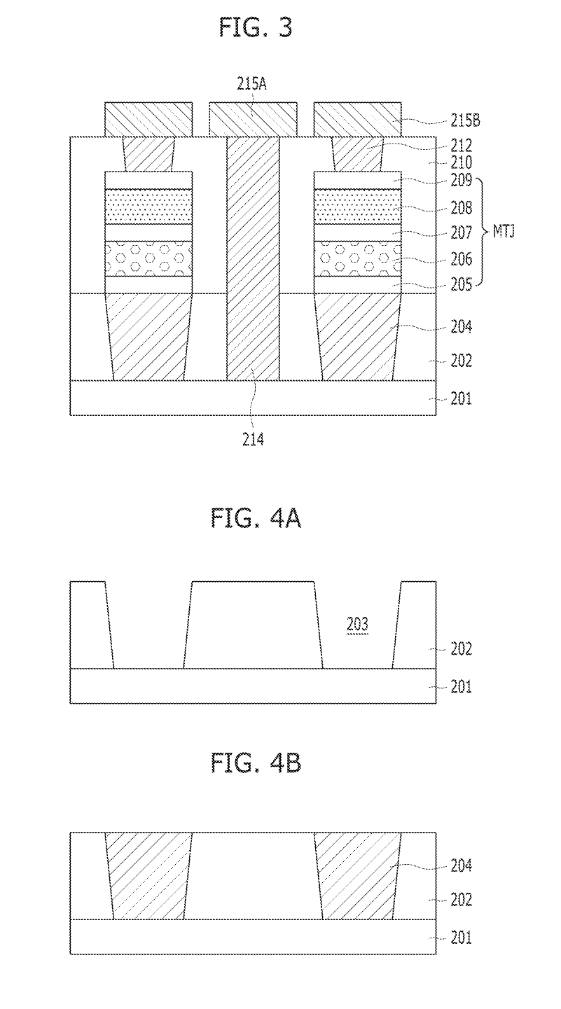

FIG. 3 is a cross-sectional view illustrating a semiconductor device according to one implementation of the disclosed technology.

As shown in FIG. 3, a semiconductor device according to this implementation may include a substrate 201 having a certain required structure formed on the substrate, e.g., a switching element, etc., a first interlayer insulating layer 102 formed on the substrate 201, and a bottom electrode contact 204 formed through the first interlayer insulating layer 202 to electrically connect one end of the switching element to a variable resistance element MTJ. The variable resistance element MTJ may be formed on the first interlayer insulating layer 202.

The variable resistance element MTJ may be formed over the first interlayer insulating layer 202. Also, the semiconductor device may further include a second interlayer insulating layer 210 that fills or is arranged between the variable resistance elements MTJ, and first and second conductive lines 215A and 215B formed over the second interlayer insulating layer 210.

In addition, the semiconductor device may further include a top electrode contact 212 formed through the second interlayer insulating layer 210 over the variable resistance element MTJ to electrically connect the variable resistance element MTJ to the second conductive line 215B.

Furthermore, the semiconductor device may include a source line contact 214 formed through the first and second interlayer insulating layers 202 and 210 between the variable resistance elements MTJ to electrically connect the first conductive line 215A to the substrate 201.

The switching element is configured to select a specific unit cell among a plurality of unit cells included in a semiconductor device. The switching element may be disposed in each unit cell, and may include a transistor, or a diode, etc. One end of the switching element may be electrically connected to a first contact plug 204, and the other end of the switching element may be electrically connected to a source line (not shown).

The first interlayer insulating layer 202 and the second interlayer insulating layer 210 may be formed of or include any one single layer selected from an oxide layer, a nitride layer or an oxynitride layer, or a stack of two or more of these layers.

The variable resistance element MTJ may include the same structure as the variable resistance element MTJ shown in FIG. 1.

The variable resistance element MTJ may include a magnetic tunnel junction (MTJ) structure including: a seed layer 205; a variable layer 206 having a variable magnetization direction; a pinned layer 208 having a fixed magnetization direction; a tunnel barrier layer 207 interposed between the variable layer 206 and the pinned layer 208; and a capping layer 209.

Herein, the variable layer 206 has a variable magnetization direction, and thus can actually store data according to the magnetization direction. It may be referred to as a free layer, or a storage layer, etc.

In particular, the variable layer 206 in this implementation may include a material capable of lowering the saturation magnetization of a ferromagnetic material, for example, a material having a standard electrode potential higher than that of Fe.

For example, the variable layer 206 may be composed of or include an alloy of a material including Fe and a material having a standard electrode potential higher than that of Fe, and in this case, the Fe content of the variable layer 206 may increase with the psotion within the variable layer 206 as the position gets closer to the interface with the tunnel barrier layer 207. In addition, the variable layer 206 may be composed of or include a stack of a material layer including Fe and a material layer having a standard electrode potential higher than that of Fe, and in this case, the material layer including Fe may be positioned in a portion that comes in contact with the tunnel barrier layer 207.

Furthermore, the variable layer 206 may include an SAF structure including a stack of a magnetic layer including a material having a standard electrode potential higher than that of Fe, a spacer layer, and a ferromagnetic layer. The spacer layer may, for example, include any one selected from Ru, Cr, Cu, Ti or W. The material having a standard electrode potential higher than that of Fe may, for example, include any one selected from Cd, Ni, Sn, Sb, Ag or Pd.

In addition, the variable layer 206 may include any one alloy selected from an Fe-Pt alloy, an Fe—Pd alloy, a Co—Fe alloy, an Fe—Ni—Pt alloy or a Co—Fe—Pt alloy, or a stack structure made of any one selected from Fe/Pd or Fe/Pt. Also, the variable layer 206 may further include an impurity such as boron (B) in the above-described alloy or stack structure.

The pinned layer 208 has a fixed magnetization direction that can be contrasted with the magnetization direction of the variable layer 206, and it may be referred to as a pinned layer, a reference layer, etc.

The pinned layer 208 may be, for example a material layer including Fe. For example, the pinned layer 208 may include a single layer including Fe—Pt alloy, an Fe—Pd alloy, a Co—Pd alloy, a Co—Pt alloy, a Co—Fe alloy, an Fe—Ni—Pt alloy, a Co—Fe—Pt alloy or a Co—Ni—Pt alloy, or a multilayer structure made of two or more of these alloys, or a stack structure including Co/Pt, Co/Pd, Fe/Pd or Fe/Pt. Also, the pinned layer 208 may further include an impurity such as boron (B) in the above-described single layer, multilayer structure or stack structure.

As described above, if the saturation magnetization (Ms) of the variable layer is lowered by adding a material having a standard electrode potential higher than that of Fe to the variable layer, it is possible to increase the thickness of the variable layer while maintaining the perpendicular magnetization properties of the variable layer. Therefore, the damping constant and spin polarization of the variable resistance element may be enhanced.

The variable layer 206 or the pinned layer 208 may include the structures shown in FIGS. 2A to 2C.

The tunnel barrier layer 207 allows the tunneling of electronsto enable a change in the magnetization direction. The tunnel barrier layer 207 may be or include a single layer or multilayer structure including a dielectric material, for example, an oxide such as Al₂O₃, MgO, CaO, SrO, TiO, VO or NbO, but is not limited thereto.

A seed layer 205 and a capping layer 209 may, for example, include Ta, Ru, PtMn, Al, Hf, Cr, W, Ti, TaN, AlN, HfN, CrN, WN or TiN, or a combination of two or more.

In this implementation, the variable layer 206 is positioned in the bottom portion of the variable resistance element and the pinned layer 208 is positioned in the top portion of the variable resistance element. However, the positions of the variable layer 206 and the pinned layer 208 are not limited thereto, and may be changed as needed. In addition, because the seed layer 205 and the capping layer 209 are layers positioned in the bottom and top portions of the variable resistance element, respectively, the positions of these layers may be maintained if the positions of the variable layer 206 and the pinned layer 208 are changed with respect to each other.

First and second conductive lines 215A and 215B may include a metallic layer. The metallic layer means a conductive layer including a metal element, and may include a metal layer, a metal oxide layer, a metal nitride layer, a metal oxynitride layer, or a metal silicide layer, etc. In addition, the first and second conductive lines 215A and 215B may be formed simultaneously using the same mask. In addition, the first and second conductive lines 215A and 215B may perform different functions depending on portions to which they are connected. In other words, the first conductive line 215A that is connected to the substrate 201 may function as a source line, and the second conductive line 215B that is electrically connected to the variable resistance element MTJ may function as a bit line.

The bottom electrode contact 204, the top electrode contact 212 and the source line contact 214 may include a semiconductor layer or a metallic layer. The bottom electrode contact 204 may function to electrically connect the variable resistance element MTJ to a switching element (not shown) and may function as a bottom electrode of the variable resistance element MTJ. The top electrode contact 212 may function to electrically connect the variable resistance element MTJ to a second conductive line 215B and may function as a top electrode of the variable resistance element MTJ. The source line contact (SLC) 214 may function to electrically connect the substrate 201 to the first conductive line 215A. The source line contacts 214 and the variable resistance elements MTJ may be alternately and repeatedly arranged such that the source line contacts 214 and the variable resistance elements MTJ do not lie on the same line.

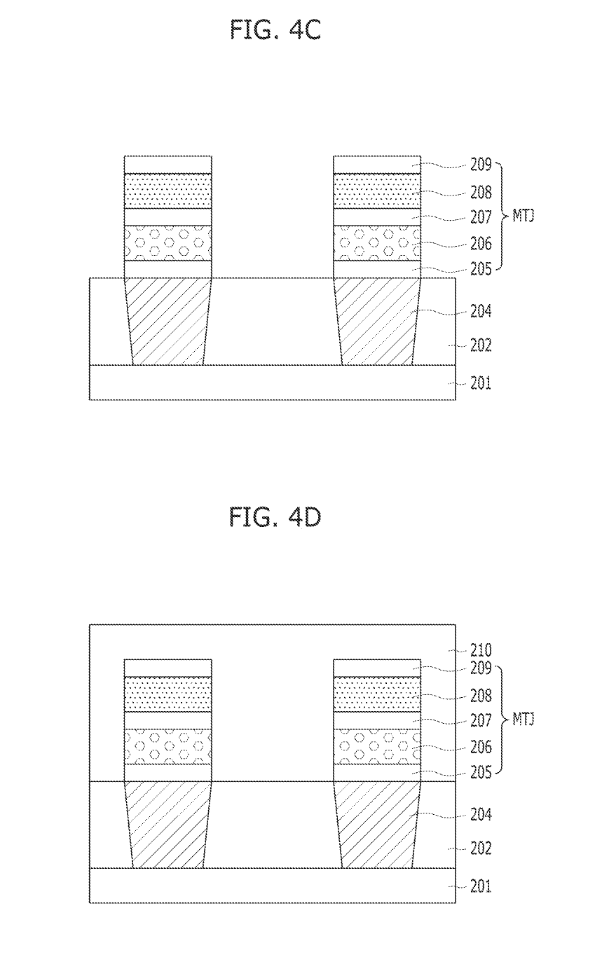

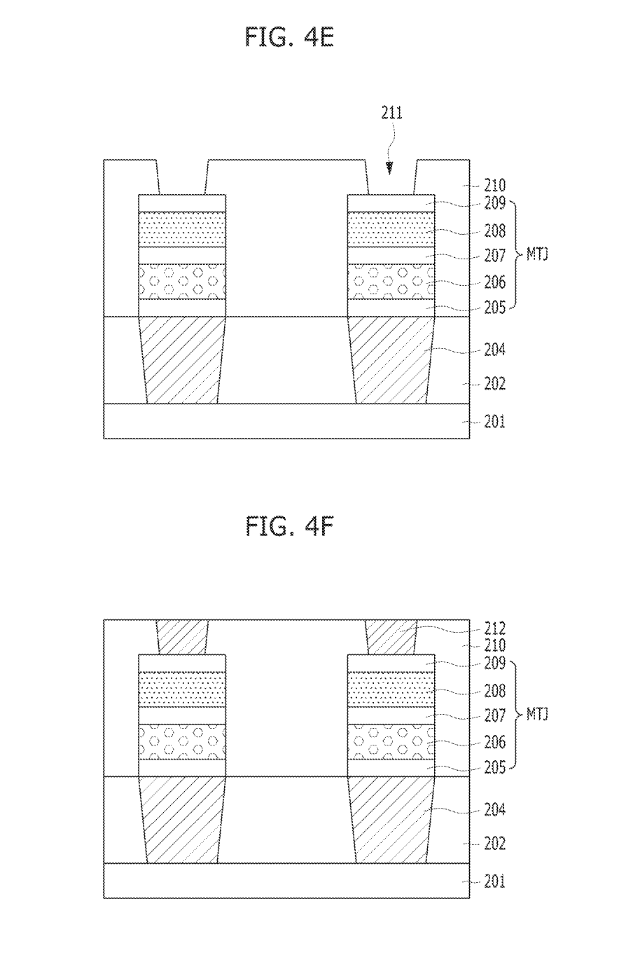

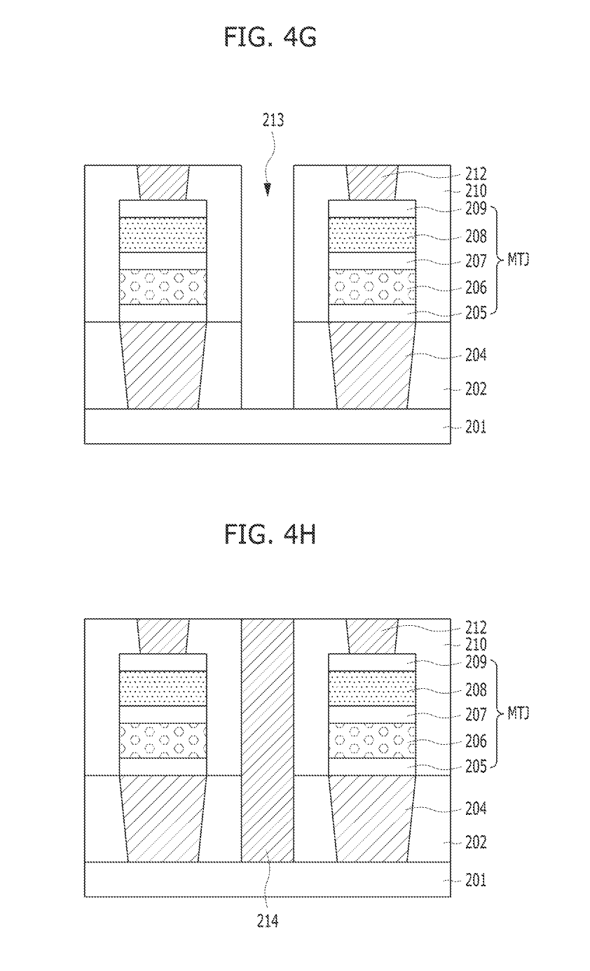

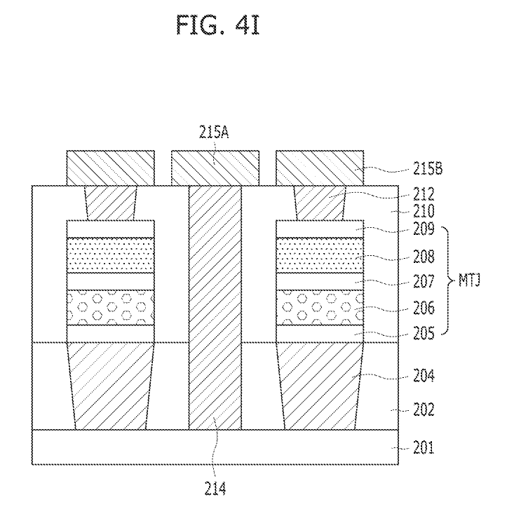

FIGS. 4A to 4I are cross-sectional views illustrating a method for fabricating a semiconductor device in accordance with one implementation of the disclosed technology. FIGS. 4A to 4I illustrate a fabrication method for forming the semiconductor device illustrated in FIG. 3. To facilitate understanding of the implementation, the same reference numerals as those in FIG. 3 are used in FIGS. 4A to 4I.

As shown in FIG. 4A, a substrate 201 having a certain structure formed on the substrate, for example, a switching element (not shown), provided. Herein, the switching element is configured to select a specific unit cell among unit cells included in a semiconductor device, and may include a transistor, or a diode, etc. One end of the switching element may be electrically connected to a bottom electrode contact as described below, and the other end thereof may be electrically connected to a source line through a source line contact as described below.

Next, a first interlayer insulating layer 202 is formed over the substrate 201. The first interlayer insulating layer 202 may be composed of or include any one single layer including an oxide layer, a nitride layer or an oxynitride layer, or a stack of two or more of these layers.

Subsequently, a first contact hole 203 is formed through the first interlayer insulating layer 202 so as to expose the substrate 201.

As shown in FIG. 4B, a conductive material is gap-filled in the first contact hole 203 to form a bottom electrode contact 204. The bottom electrode contact 204 may be formed through a series of process steps including forming a conductive material over the surface so as to gap-fill the first contact hole 203 (see FIG. 4A), and performing an isolation process to electrically isolate adjacent bottom electrode contacts 204 from each other. The isolation process may be performed by etching or polishing the conductive material, formed all over the surface, using a blanket etching (e.g., etchback) process or a chemical mechanical polishing

(CMP) process until the first interlayer insulating layer 202 is exposed.

As shown in FIG. 4C, a variable resistance element MTJ is formed over the first interlayer insulating layer 202 including the bottom electrode contact 204. The variable resistance element MTJ may include a stack including a seed layer 205, a variable layer 206, a tunnel barrier layer 207, a pinned layer 208 and a capping layer 209, and may further include a protective layer (not shown) formed on the sidewall of the stack structure. In addition, the variable resistance element MTJ may further include a barrier layer for enhancing the characteristics of each magnetic layer.

The variable resistance element MTJ may include the same structure and material as those described with reference to FIG. 3.

As shown in FIG. 4D, a second interlayer insulating layer 210 may be formed on the first interlayer insulating layer 202. The second interlayer insulating layer 210 may be formed to a thickness sufficient for filling between the variable resistance elements MTJ. For example, the second interlayer insulating layer 210 may be formed to have a surface level higher than the top surface of the variable resistance layer MTJ. The second interlayer insulating layer 210 may be formed to include the same material as that of the first interlayer insulating layer 202. The second interlayer insulating layer 210 may be formed of or include, for example, any one single layer including an oxide layer, a nitride layer or an oxynitride layer, or a stack of two or more of these layers.

As shown in FIG. 4E, the second interlayer insulating layer 210 may be selectively etched to form a second contact hole 211 that exposes the top surface of the variable resistance element MTJ.

As shown in FIG. 4F, a conductive material is filled in the second contact hole 211 to form a top electrode contact 212. The top electrode contact 212 may function to electrically connect the variable resistance element MTJ with a conductive line to be formed in a subsequent process, and may function as an electrode of the variable resistance element MTJ.

The top electrode contact 212 may be formed by a series of process steps including forming a conductive material over the surface so as to gap-fill the second contact hole 211 (see FIG. 4E), and performing an isolation process to electrically isolate adjacent top electrode contacts 204 from each other. The isolation process may be performed by etching or polishing the conductive material, formed over the surface, using a blanket etching (e.g., etchback) process or a chemical mechanical polishing (CMP) process until the second interlayer insulating layer 210 is exposed.

As shown in FIG. 4G, the first and second interlayer insulating layers 202 and 210 between the variable resistance elements MTJ may be selectively etched to form a third contact hole 213 that exposes the substrate 201.

The third contact holes 213 and the variable resistance elements MTJ may be arranged alternately such that they do not lie on the same line.

As shown in FIG. 4H, a conductive material is filled in the third contact hole 213 (see FIG. 4G) to form a source line contact 214. The source line contact 214 may be or include a contact plug that electrically connects the substrate 201 to a conductive line (i.e., a source line) that is to be formed by a subsequent process.

As shown in FIG. 4I, first and second conductive lines 215A and 215B may be formed on the second interlayer layer 210 including the top electrode contact 212 and the source line contact 214.

The first and second conductive lines 215A and 215B may include a metallic layer. The metallic layer means a conductive layer including a metal element, and may include a metal layer, a metal oxide layer, a metal nitride layer, a metal oxynitride layer, or a metal silicide layer, etc. In addition, the first and second conductive lines 215A and 215B may be formed simultaneously using the same mask. Also, the first and second conductive lines 215A and 215B may perform different functions depending on portions to which they are connected. For example, the first conductive line 215A that is connected to the substrate 201 may function as a source line, and the second conductive line 215B that is electrically connected to the variable resistance element MTJ may function as a bit line.

As described above, according to the electronic device including the semiconductor memory and the fabrication method thereof according to the above-described implementations, the characteristics of the variable resistance element can be improved.

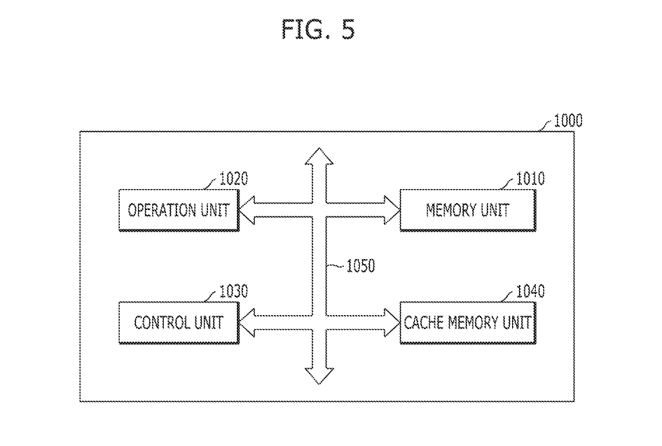

The above and other memory circuits or semiconductor devices based on the disclosed technology can be used in a range of devices or systems. FIGS. 5-9 provide some examples of devices or systems that can implement the memory circuits disclosed herein.

FIG. 5 is an example of configuration diagram of a microprocessor implementing memory circuitry based on the disclosed technology.

Referring to FIG. 5, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and addresses where data for performing of the operations are stored.

The memory unit 1010 may include one or more of the above-described semiconductor devices in accordance with the implementations. For example, the memory unit 1010 may include a variable resistance element including a stack of a pinned layer, a tunnel barrier layer and a variable layer, wherein the variable layer may include a material layer having a standard electrode potential higher than that of iron (Fe). Through this, a fabrication process of the memory unit 1010 may become easy and the reliability and yield of the memory unit 1010 may be improved. As a consequence, operating characteristics of the microprocessor 1000 may be improved.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

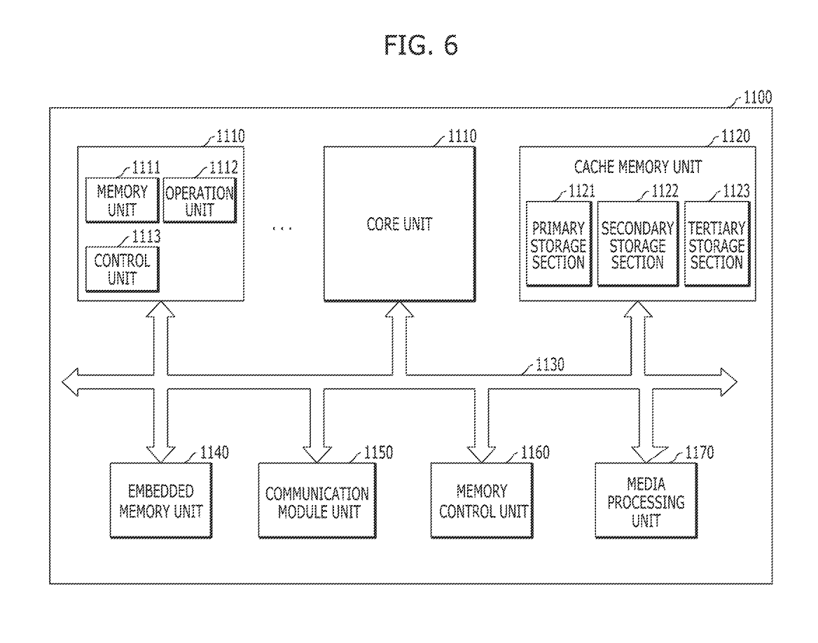

FIG. 6 is an example of configuration diagram of a processor implementing memory circuitry based on the disclosed technology.

Referring to FIG. 6, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and addresses where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor 1100, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122 and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest. At least one storage section of the primary storage section 1121, the secondary storage section 1122 and the tertiary storage section 1123 of the cache memory unit 1120 may include one or more of the above-described semiconductor devices in accordance with the implementations. For example, the cache memory unit 1120 may include a variable resistance element including a stack of a pinned layer, a tunnel barrier layer and a variable layer, wherein the variable layer may include a material layer having a standard electrode potential higher than that of iron (Fe). Through this, a fabrication process of the cache memory unit 1120 may become easy and the reliability and yield of the cache memory unit 1120 may be improved. As a consequence, operating characteristics of the processor 1100 may be improved.

Although it was shown in FIG. 6 that all the primary, secondary and tertiary storage sections 1121, 1122 and 1123 are configured inside the cache memory unit 1120, it is to be noted that all the primary, secondary and tertiary storage sections 1121, 1122 and 1123 of the cache memory unit 1120 may be configured outside the core unit 1110 and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed. In another implementation, the primary and secondary storage sections 1121, 1122 may be disposed inside the core units 1110 and tertiary storage sections 1123 may be disposed outside core units 1110.

The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

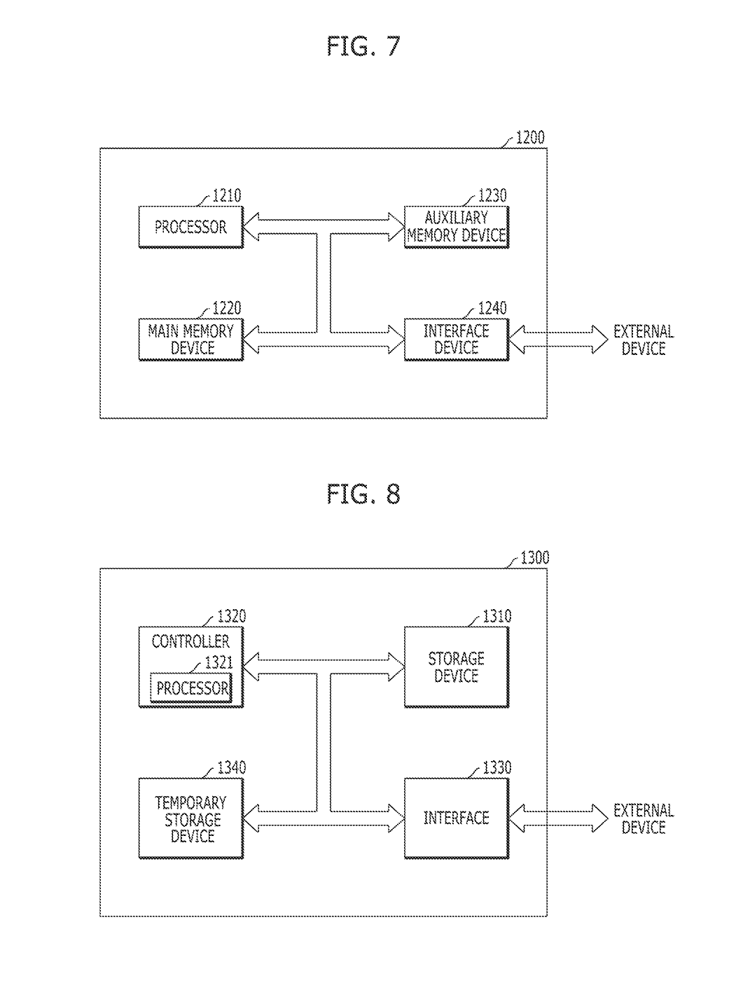

FIG. 7 is an example of configuration diagram of a system implementing memory circuitry based on the disclosed technology.

Referring to FIG. 7, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 may include a variable resistance element including a stack of a pinned layer, a tunnel barrier layer and a variable layer, wherein the variable layer may include a material layer having a standard electrode potential higher than that of iron (Fe). Through this, a fabrication process of the main memory device 1220 may become easy and the reliability and yield of the main memory device 1220 may be improved. As a consequence, operating characteristics of the system 1200 may be improved.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 may include a variable resistance element including a stack of a pinned layer, a tunnel barrier layer and a variable layer, wherein the variable layer may include a material layer having a standard electrode potential higher than that of iron (Fe). Through this, a fabrication process of the auxiliary memory device 1230 may become easy and the reliability and yield of the auxiliary memory device 1230 may be improved. As a consequence, operating characteristics of the system 1200 may be improved.

Also, the auxiliary memory device 1230 may further include a data storage system (see the reference numeral 1300 of FIG. 8) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 8) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network and both of them. The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 8 is an example of configuration diagram of a data storage system implementing memory circuitry based on the disclosed technology.

Referring to FIG. 8, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller and a system. The temporary storage device 1340 for temporarily storing data may include one or more of the above-described semiconductor devices in accordance with the implementations. The temporary storage device 1340 may include a variable resistance element including a stack of a pinned layer, a tunnel barrier layer and a variable layer, wherein the variable layer may include a material layer having a standard electrode potential higher than that of iron (Fe). Through this, a fabrication process of the storage device 1310 or the temporary storage device 1340 may become easy and the reliability and yield of the storage device 1310 or the temporary storage device 1340 may be improved. As a consequence, operating characteristics and data storage characteristics of the data storage system 1300 may be improved.

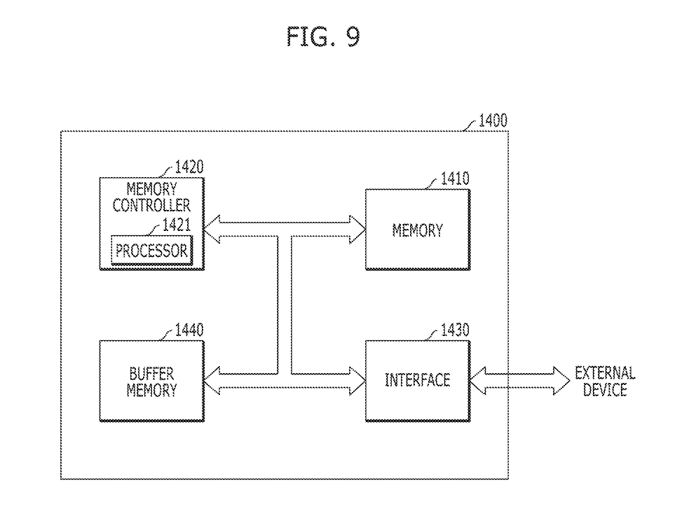

FIG. 9 is an example of configuration diagram of a memory system implementing memory circuitry based on the disclosed technology.

Referring to FIG. 9, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 may include a lower electrode; a variable resistance element over the lower electrode; an upper electrode disposed over the variable resistance element and including metal; and a metal compound layer configured to surround a side of the upper electrode, wherein the metal compound layer comprises a compound of the metal of the upper electrode. Through this, a fabrication process of the memory 1410 may become easy and the reliability and yield of the memory 1410 may be improved. As a consequence, operating characteristics and data storage characteristics of the memory system 1400 may be improved.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described semiconductor devices in accordance with the implementations. The buffer memory 1440 may include a variable resistance element including a stack of a pinned layer, a tunnel barrier layer and a variable layer, wherein the variable layer may include a material layer having a standard electrode potential higher than that of iron (Fe). Through this, a fabrication process of the buffer memory 1440 may become easy and the reliability and yield of the buffer memory 1440 may be improved. As a consequence, operating characteristics and data storage characteristics of the memory system 1400 may be improved.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

Features in the above examples of electronic devices or systems in FIGS. 5-9 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. An electronic device comprising a semiconductor memory, the semiconductor memory comprising a variable resistance element comprising a stack of a pinned layer, a tunnel barrier layer and a variable layer, wherein the variable layer includes a material layer having a standard electrode potential higher than that of Fe.

2. The electronic device of claim 1, wherein the pinned layer includes a material layer including Fe.

3. The electronic device of claim 1, wherein the variable layer includes an alloy of a material including Fe and a material having a standard electrode potential higher than that of Fe, and a content of Fe in the variable layer spatially increases towards the tunnel barrier layer.

4. The electronic device of claim 1, wherein the variable layer includes a stack of a material layer including Fe and a material layer having a standard electrode potential higher than that of Fe, and the material layer including Fe is positioned in a portion that comes in contact with the tunnel barrier layer.

5. The electronic device of claim 1, wherein the variable layer includes an SAF (Synthetic Antiferromagnetic) structure comprising a stack of a magnetic layer including a material having a standard electrode potential higher than that of Fe, a spacer layer and a ferromagnetic layer.

6. The electronic device of claim 5, wherein the spacer layer includes Ru, Cr, Cu, Ti or W.

7. The electronic device of claim 1, wherein the material layer having a standard electrode potential higher than that of Fe includes Cd, Ni, Sn, Sb, Ag or Pd.

8. The electronic device of claim 1, wherein the variable layer includes any alloy including Fe—Pt alloy, Fe—Pd alloy, Co—Fe alloy, Fe—Ni—Pt alloy or Co—Fe—Pt alloy, or a stack structure including Fe/Pd or Fe/Pt.

9. The electronic device of claim 8, wherein the variable layer further includes boron (B) as an impurity in the alloy or the stack structure.

10. The electronic device of claim 1, wherein the pinned layer includes a single layer including an Fe—Pt alloy, an Fe—Pd alloy, a Co—Pd alloy, a Co—Pt alloy, a Co—Fe alloy, an Fe—Ni—Pt alloy, a Co—Fe—Pt alloy or a Co—Ni—Pt alloy, or a multilayer structure including two or more of the Fe—Pt alloy, the Fe—Pd alloy, the Co—Pd alloy, the Co—Pt alloy, the Co—Fe alloy, the Fe—Ni—Pt alloy, the Co—Fe—Pt alloy or the Co—Ni—Pt alloy, or a stack structure including Co/Pt, Co/Pd, Fe/Pd or Fe/Pt.

11. The electronic device of claim 10, wherein the pinned layer further includes boron (B) as an impurity in the single layer, the multilayer structure or the stack structure.

12. The electronic device of claim 1, wherein the variable resistance element further includes a seed layer located in bottom portion of the variable resistance element, and a capping layer located in top portion of the variable resistance element.

13. The electronic device of claim 12, wherein the seed layer or the capping layer includes any one or a combination of two or more selected from Ta, Ru, PtMn, Al, Hf, Cr, W, Ti, TaN, AlN, HfN, CrN, WN or TiN.

14. The electronic device of claim 1, wherein the tunnel barrier layer includes a single layer including Al₂O₃, MgO, CaO, SrO, TiO, VO or NbO, or a multilayer structure including two or more of Al₂O₃, MgO, CaO, SrO, TiO, VO or NbO.

15. The electronic device according to claim 1, further comprising a microprocessor which includes:
a control unit configured to receive a signal including a command from an outside of the microprocessor, and performs extracting, decoding of the command, or controlling input or output of a signal of the microprocessor;
an operation unit configured to perform an operation based on a result that the control unit decodes the command; and
a memory unit configured to store data for performing the operation, data corresponding to a result of performing the operation, or an address of data for which the operation is performed,
wherein the semiconductor memory unit that includes the resistance variable element is part of the memory unit in the microprocessor.

16. The electronic device according to claim 1, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory unit that includes the resistance variable element is part of the cache memory unit in the processor.

17. The electronic device according to claim 1, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between at least one of the processor, the auxiliary memory device and the main memory device and the outside,
wherein the semiconductor memory unit that includes the resistance variable element is part of the auxiliary memory device or the main memory device in the processing system.

18. The electronic device according to claim 1, further comprising a data storage system which includes:
a storage device configured to store data and conserve stored data regardless of power supply;
a controller configured to control input and output of data to and from the storage device according to a command inputted form an outside;
a temporary storage device configured to temporarily store data exchanged between the storage device and the outside; and
an interface configured to perform communication between at least one of the storage device, the controller and the temporary storage device and the outside,
wherein the semiconductor memory unit that includes the resistance variable element is part of the storage device or the temporary storage device in the data storage system.

19. The electronic device according to claim 1, further comprising a memory system which includes:
a memory configured to store data and conserve stored data regardless of power supply;
a memory controller configured to control input and output of data to and from the memory according to a command inputted form an outside;
a buffer memory configured to buffer data exchanged between the memory and the outside; and
an interface configured to perform communication between at least one of the memory, the memory controller and the buffer memory and the outside,
wherein the semiconductor memory unit that includes the resistance variable element is part of the memory or the buffer memory in the memory system.
